(19) United States
(12) Patent Application Publication
(10) Pub. No.: US 2011/0291804 A1
(43) Pub. Date: Dec. 1, 2011

(54) TACTILE PAVING PAD, TACTILE SYSTEM AND METHOD

(76) Inventor: Chun Alain CHAN, Hong Kong (HK)

(21) Appl. No.: 13/047,808

(22) Filed: Mar. 15, 2011

(30) Foreign Application Priority Data
May 28, 2010 (CN) 201010185913.7

(51) Int. Cl. H04Q 5/22; H05K 7/02

(52) U.S. Cl. 340/10.1; 361/679.01

(57) ABSTRACT

A replaceable tactile paving pad with electronic components is disclosed. The tactile paving pad comprises a base, a plurality of protrusions extending upwards from the base, a duct portion comprising at least one duct provided on a top surface of the base with an opening provided on the top surface facing upwards, the duct portion extends along a whole length of the base, and an electronic component received within the duct. A system is also disclosed, the system comprising at least one pad and a remote device. The remote device comprises a wireless reader, an input device and an output device. The wireless reader communicates with wireless devices in each pad and a backend server and alerts a user with information retrieved from the backend server.

### CROSS-REFERENCE TO RELATED APPLICATION

This application claims benefit under 35 U.S.C. §119 of China Invention Patent Application having Serial No. 201010185913.7 filed May 28, 2010, which is hereby incorporated by reference herein in its entirety.

### FIELD OF INVENTION

This invention relates to a tactile paving pad, and in particular a replaceable tactile paving pad with electronic component.

### BACKGROUND OF INVENTION

Tactile paving pads are commonly used all over the world to aid or guide users that are blind or visually impaired. However, conventional tactile paving pads do not fulfill its full potential in guiding users.

### SUMMARY OF INVENTION

In the light of the foregoing background, it is an object of the present invention to provide an alternate tactile paving pad.

Accordingly, the present invention, in one aspect, is a tactile paving pad comprising a base and a plurality of protrusions extending upwards from the base. The pad comprises a duct portion, in which at least one duct is provided on a top surface of the base. The duct portion extends through a whole length of the base. An electronic component is received within the duct.

In one embodiment of the present invention, the electronic component comprises a light emitting diode strip. In another embodiment of the present invention, the electronic component comprises a wireless communication device.

In another exemplary embodiment, the duct portion is located towards one side of the pad base.

According to another aspect of the present invention, a system comprising at least one tactile paving pad is disclosed. Each tactile paving pad comprises a base, a plurality of protrusions extending upwards from the base and a duct portion having at least one duct, the duct having an opening facing upwards and the duct portion extending through a whole length of the base. A wireless communication device is provided in the duct of the pad. The system further comprises a remote device having a wireless reader, an input device and an audio output device. The wireless communication device of each pad and the wireless reader are connected to a backend server. The backend server retrieves a request for information entered by a user into the input device, and alerts the user with the information through the output device.

In an embodiment, each pad further comprises a light emitting diode strip. In another embodiment, each pad further comprises at least one opening for removably coupling to a coupling unit. The coupling unit comprises a fixed portion adapted to be fixed to an environment surrounding the fixed portion, and a removable portion extending through the opening and removably coupled to the fixed portion.

There are many advantages to the present invention. One advantage is that the light emitted from the LED strip provides additional alert to visually impaired users. Whereas a conventional pad may be hard to notice by such users especially in crowded areas, the light emitted from the pad make the users recognize the location of the pad much more easily.

Another advantage of the present invention is that the pad is also used for interactive guiding of users. The user can input a desired location in the remote device, then the remote device alerts the user with the information transmitting through the pads. The pads with location information and the backend server form a real time location system that enables a direction to a specific location be sent to the user depending on the location of the pad.

Another advantage of the present invention is that the pad is replaceable individually even with electronic components. The expectancy of a conventional pad made of fiberglass is about three to five years, and the pad and cement beneath both need to be removed if the pad is to be replaced. In this invention, the cement does not need to be repaved because a coupling unit is already fixed to the cement for coupling to the pad. The electronic component such as LED strip is also designed to be removable with an individual pad.

Another advantage of the present invention is that deformation of pad over time is reduced by locating the duct portion towards one side of the pad. As time passes, the pad will deform as the difference in thickness of the pad at the duct makes the pad expand and contract at a different rate across the pad. In the present invention, the displacement is reduced since the size of a deformed portion (always a minor portion) is minimized.

### BRIEF DESCRIPTION OF FIGURES

FIG. 1 is a top view of a tactile paving pad according to an embodiment of the present invention.

FIG. 2 is a side view of the tactile paving pad of FIG. 1.

FIG. 3 is a top view of a tactile paving pad according to another embodiment of the present invention.

FIG. 4 is a perspective view of a LED strip according to an embodiment of the present invention.

FIG. 5 is a cross sectional view of the duct portion of the embodiment in FIG. 3, showing how the LED strip can be received.

FIG. 6 is a top view of a tactile paving pad unit of a system according to an embodiment of the present invention.

FIG. 7a is a signal flow of a tactile paving pad system according to an embodiment of the present invention.

FIG. 7b is a signal flow of a tactile paving pad system according to another embodiment of the present invention.

FIG. 7c is a signal flow of a tactile paving pad system according to another embodiment of the present invention.

FIG. 8 is a top view of a tactile paving pad according to another embodiment of the present invention.

FIG. 9 is a cross sectional view of the pad of FIG. 8 along an opening with coupling unit coupled thereto.

FIG. 10 is a flow chart of installing the tactile paving pad of FIG. 8 on cement.

### DETAILED DESCRIPTION OF THE PREFERRED EMBODIMENTS

While the present invention is described herein with reference to illustrative embodiments for particular applications, it should be understood that the invention is not limited thereto. Those skilled in the art with access to the teachings provided herein will recognize additional modifications, applications, and embodiments within the scope thereof and additional fields in which the invention would be of significant utility.

As used herein and in the claims, “comprising” means including the following elements but not excluding others.

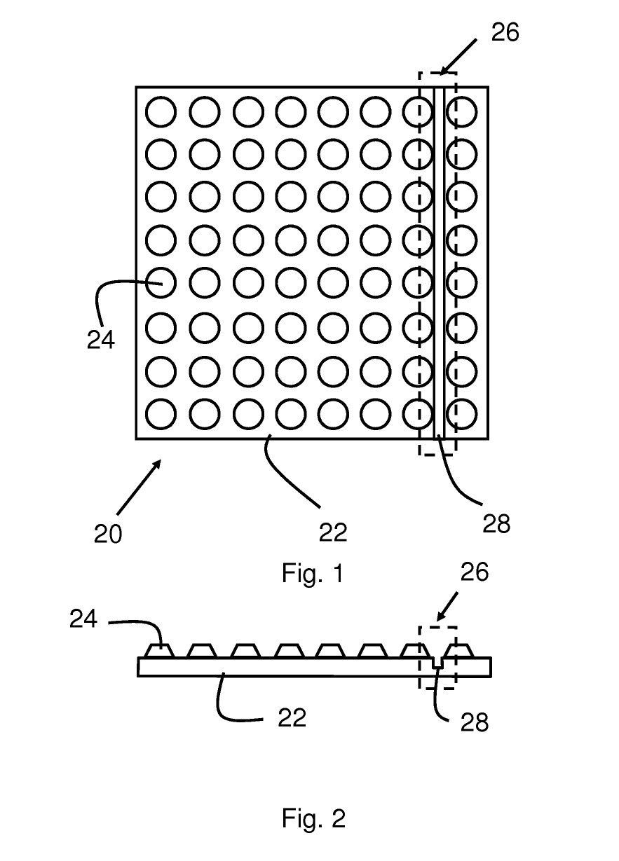

Referring now to FIGS. 1 and 2, the first embodiment of the present invention is a tactile paving pad 20 (hereinafter pad) comprising a substrate or base 22 and a plurality of protrusions 24 protruding upwards from a top surface of the base 22. In this embodiment, the protrusions 24 form an 8×8 array of truncated cones. A duct portion 26 comprising a channel or duct 28 is provided at a top surface of the base 22 with an opening facing upwards along a whole length of the duct 28. The duct 28 runs in a direction parallel to an edge of the base 22, and the duct portion 26 is defined to extend through a whole length of the base 22 along the direction of the duct 28. In the embodiment as shown, the duct 28 also extends through a whole length of the base 22. The duct 28 is provided to receive an electronic component, which is described in more detail below.

In an exemplary embodiment, the duct portion 26 is located towards a side of the pad 20 instead of being located on a central axis of the pad 20. For example, in this embodiment the duct portion 26 is located at one column of protrusions 24 away from an edge of the base 22.

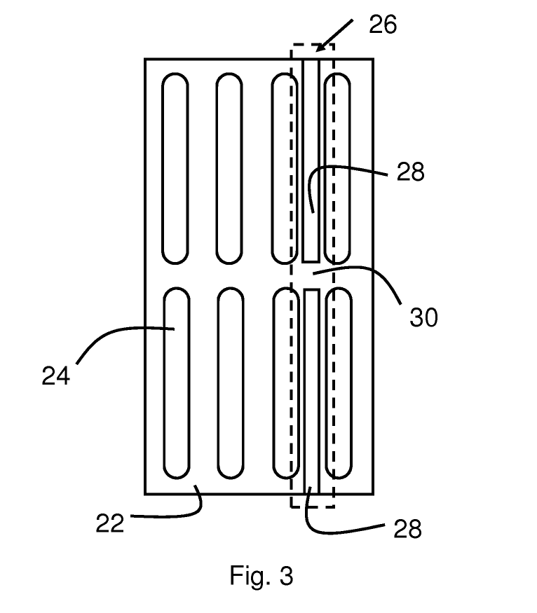

In an embodiment as shown in FIG. 3, the protrusions 24 form a 2×4 array of directional bars. The duct portion 26 is located at one column of directional bars away from an edge of the base 22. The duct portion 26 comprises a plurality of ducts 28 extending along a same longitudinal axis parallel to the directional bars, and also comprises an interruption 30 between the ducts 28 that separates adjacent ducts 28. In this embodiment, there are two ducts 28 separated in the middle by one interruption 30. The length of the interruption 30 aligns with the length of a gap between adjacent rows of directional bars.

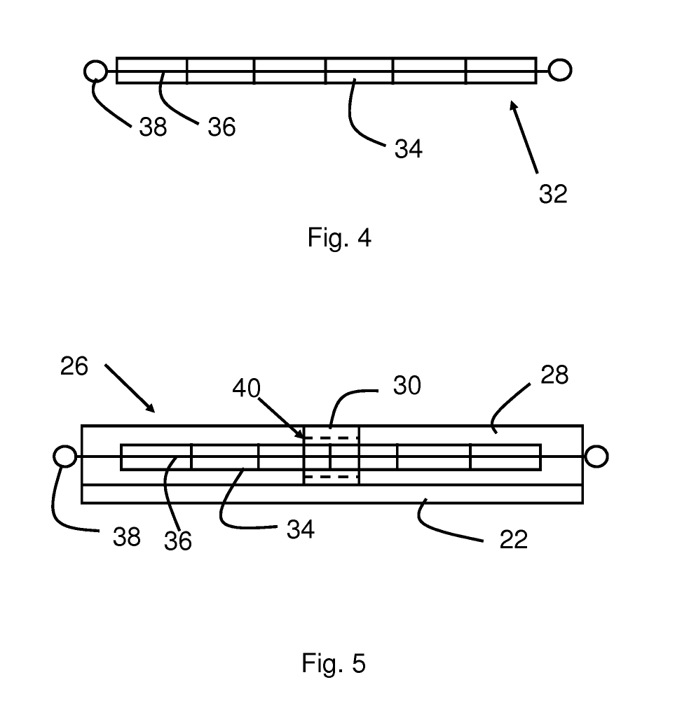

The duct 28 is provided to receive an electronic component. In an exemplary embodiment, the electronic component comprises a light emitting diode (LED) strip 32 as shown in FIG. 4. The LED strip comprises a plurality of LEDs 34 electrically connected by electrical wires 36. The LED strip 32 is completely received within the duct 28 with the LEDs generally facing upwards, meaning the whole strip is below the top surface of the base 22 in a received position. In an exemplary embodiment, the color of light that the LEDs emit is safety yellow, or any other color that satisfies the requirements of a specific country for warning color. In one embodiment, the LED strip 32 has approximately a same length or slightly longer than the pad 20 along the direction of the duct portion 26. The LED strip 32 is aligned to the pad 20 such that both ends of the string are located about an edge of the pad 20. The LED strip 32 terminates with a connector 38 at both ends. The connector 38 is adapted to electrically connect to another connector 38 of another LED strip 32, which is placed in the duct 28 of an adjacent pad 20 for example. The connector 38 can also electrically connect to a power supply or other external electrical components. In an exemplary embodiment, all the LEDs 34 are connected in parallel. In another embodiment, a small number of LEDs are connected in series, and these groups are in turn connected in parallel such that the effect to other LEDs will be minimized when one LED is dysfunctional.

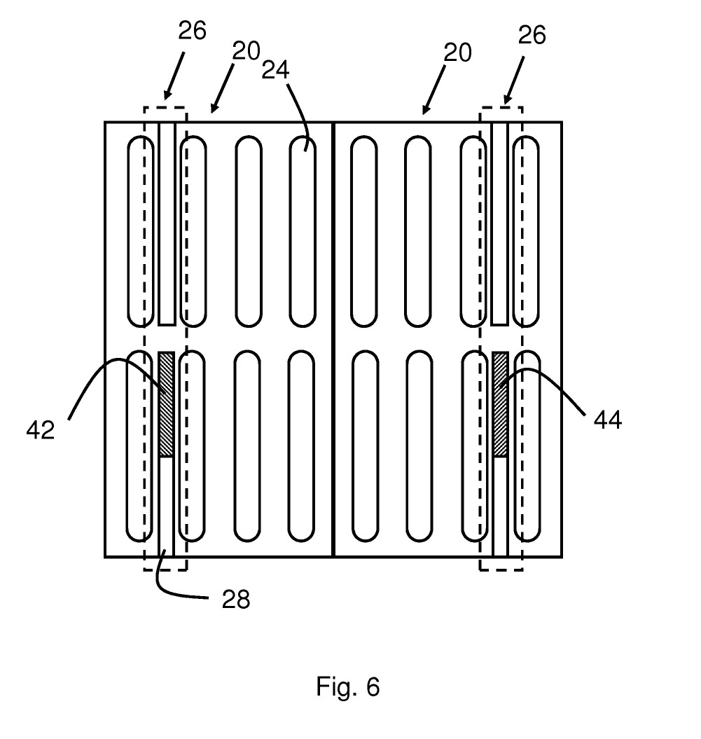

FIG. 5 shows how an LED strip 32 can be received in the duct portion 26 of the embodiment as shown in FIG. 3. A hole 40 is drilled through the interruption 30 to connect ends of adjacent ducts 28, and the LED strip 32 is inserted through the hole 40. The hole 40 prevents the middle of the LED strip 32 to move upwards, which helps to fix the LED strip to the pad 20, especially when a plurality of LED strips 32 are connected together.

In another exemplary embodiment, the electronic component comprises a wireless communication device, such as a radio-frequency (RF) device. The RF device can comprise a transmitter, a receiver and/or a transceiver. A system that utilizes such a pad 20 with wireless communication device is described below.

Referring to FIG. 6, a unit of the system mentioned above is disclosed. Each unit comprises a first and a second pad 20 which are placed side by side with the duct portions 26 of the pads 20 being arranged to be parallel to each other and located towards an exterior edge of the combined unit. An RF device 42 is provided within each of the pads 20. In another embodiment, each unit only comprises a single pad 20 with the duct portion 26 and a single RF device 42.

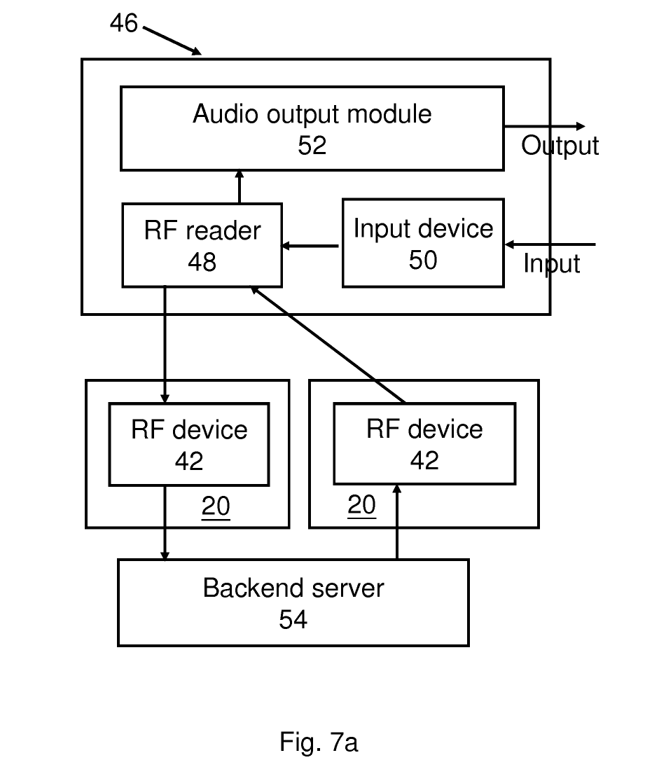

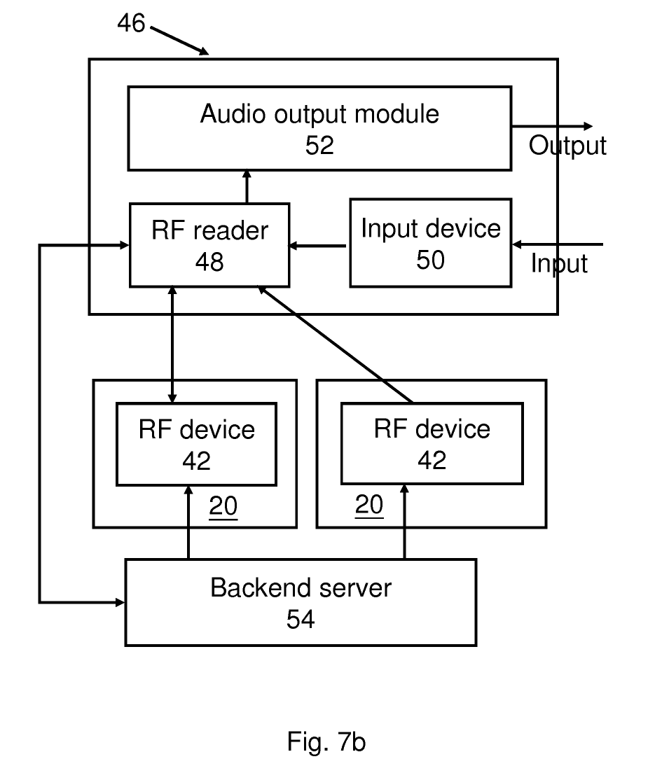

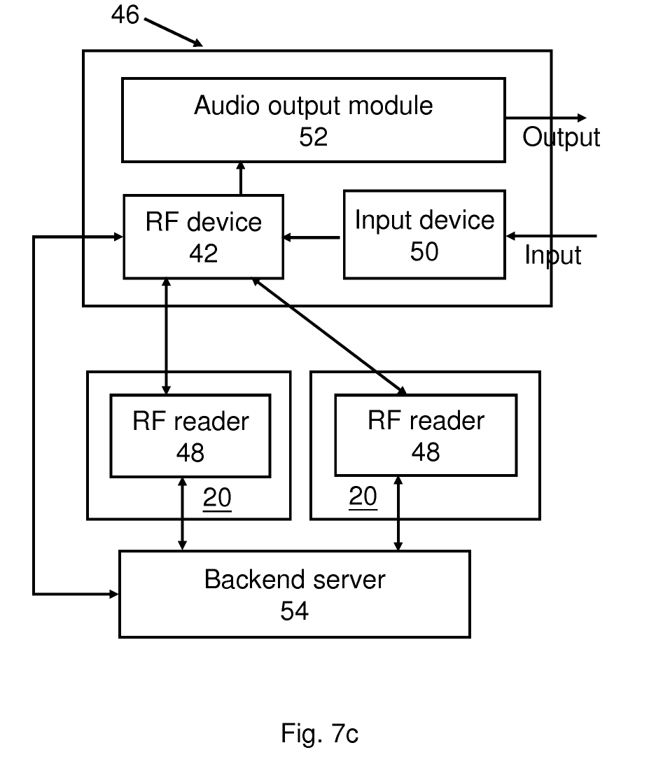

FIG. 7a shows a block diagram of a remote device 46 to be used with the pad 20 above, according to one embodiment. The remote device 46 comprises a RF reader 48 (also referred as a wireless reader) that communicates with the RF device 42 mentioned above. The remote device 46 also comprises an input device 50 and an audio output device 52 connected to the RF reader 48. In an exemplary embodiment, the remote device 46 is shaped like a pair of eye-glasses. In another exemplary embodiment, the remote device 46 is shaped like a cane or a mobile phone or other hand-held devices.

Again referring to FIG. 7a, a signal flow of the system in operation according to an embodiment is illustrated. A user with the remote device 46 enters information that the user desires to know into the input device 50. The input device 50 then sends a signal representing the information to the RF reader 48, and the signal is then wirelessly transmitted to the RF device 42 in the first pad 20. The RF device 42 in turn sends the signal with other details that may be needed to a backend server 54 through wired or wireless communication, in which the information is stored. The backend server 54 retrieves the information and sends it to the RF device 42 in the second pad 20. The RF device 42 wirelessly sends the information to the RF reader 48 in the remote device 46, then the RF reader 48 relays the information to the audio output device 52. The audio output device 52 outputs the information in an audio format to alert the user with the desired information. In a variation of the aforementioned embodiment, a single pad may equip both the receiving and the transmitting RF devices 42 so the first and second pad can be the same pad.

The information as mentioned above can be any kind of information, preferably location information. In one embodiment, the information is location information of a specific product within a shop, or location information of a specific shop within a shopping mall etc. In another embodiment, the information sent back from the server includes the routing information to guide the user to the place that he wants to go.

In one embodiment according to FIG. 7b, each pad 20 has a RFID (Radio Frequency IDentification) tag associated with it. When the user submits a request of directions to a destination for example, the RF reader 48 reads the RFID tag of the closest pad 20. In one embodiment, this is determined as the pad 20 with the strongest detected signal. In other embodiments, other methods such as the average signal strength within a time window can be used. The RF reader 48 can be designed to be highly localized in order to more accurately determine the closest pad 20. The RF reader 48 then forwards the ID code of the tag to the backend server 54 directly. The backend server 54 finds a location of the pad from the ID code, and provides direction to the user to the destination depending on the location of the pad.

In this case, the RFID tag is the RF device 42, and typically tags of different pads do not interconnect with each other. The RF reader 48 energizes the tag and the tag review its ID code back to the reader. In one embodiment, the RF reader 48 has a short enough reading distance such that the RF reader 48 can only be in close proximity to a single pad 20 to read the RFID tag. Therefore, when an RFID tag responds to the RF reader 48, the pad 20 associated to that tag is determined to be the closest in proximity.

In another embodiment as shown in FIG. 7c, the RFID tag is associated to the remote device 46 instead of the pad 20. In this embodiment, the RF reader 48 is provided in the pad 20 and the RF device 42 with the RFID tag is provided in the remote device 46 instead. The RF reader 48 forwards the ID code of the tag to the backend server 54. The backend server 54 retrieves the location of the user through the RFID tag and provides direction to the user directly to the remote device 46 or through the pads 20. In this embodiment, the location information of the pads 20 needs to be stored in the backend server 54. The RF device 42 further needs to send the desired information that the user wants to go to the backend server 54 separately. Associating the RFID tag to the remote device 46 increases the accuracy of the estimation of the user's location.

In one embodiment, the LED strip 32 is also provided in the duct 28 of the pads 20. In a further embodiment, the LED strip 32 is connected to the RF device 42, and emits light in different patterns depending on the situation. In one embodiment, the LEDs may flash to indicate “stop”, and may light continuously to indicate “go”. In one embodiment, after the user submits a request, the LEDs emit light in a specific sequence to guide the user to a specific location. For example, the LED strips 32 of the pads 20 can sequentially light up to guide the user in a specific direction.

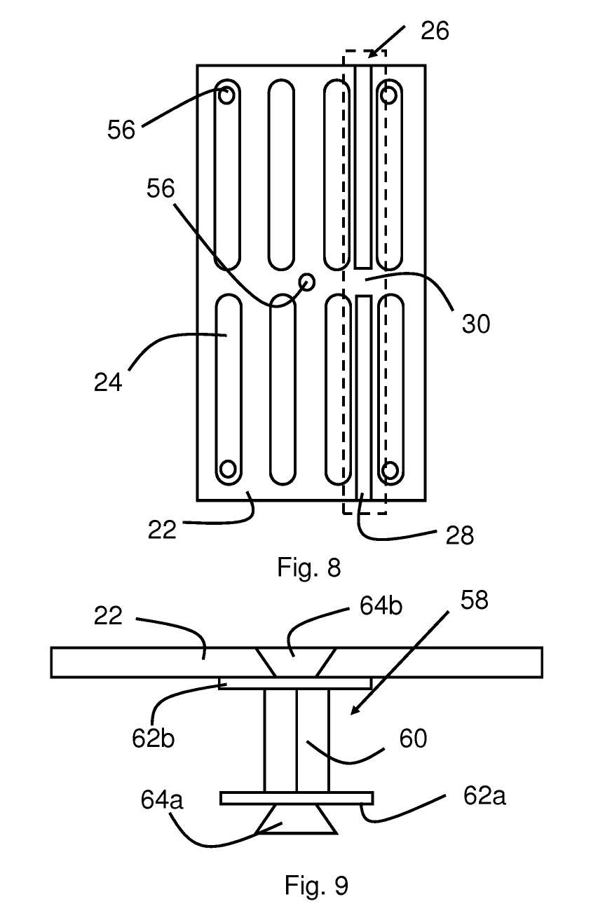

In an exemplary embodiment, the pad 20 is replaceable. As shown in FIGS. 8 and 9, an embodiment of a replaceable pad 20 comprises at least one opening 56 that extends through the pad 20 from the top surface to a bottom surface. The opening 56 can be located on the base 22 or the protrusions 24. A coupling unit 58 is provided through each opening 56 to removably attach the pad 20 to an environment beneath the pad 20, such as cement. The coupling unit 58 comprises a nut 60, with a washer either side of the nut 60. In an embodiment, the nut 60 is a hexagonal nut. A bottom screw 64a extends through a bottom washer 62a and is screwed onto the nut 60. A top screw 64b extends through the pad 20 and a top washer 62b and is screwed onto the nut 60. In an exemplary embodiment, the screw heads are flat or countersunk, and the opening 56 in the pad 20 tapers from the top surface to the bottom surface to match the tapering face of the screw heads.

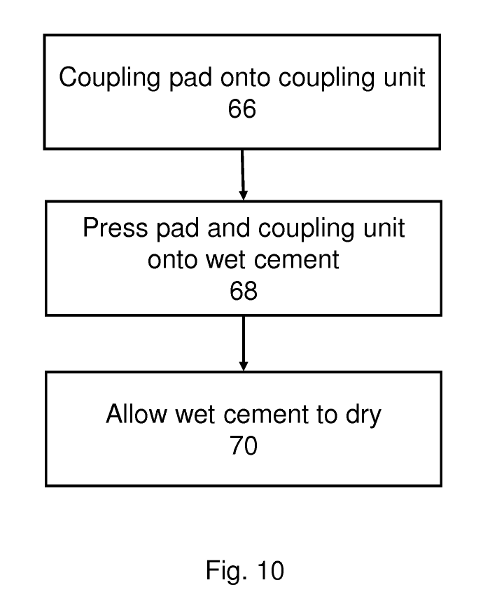

FIG. 10 shows a flow chart of installing the pad 20 according to an embodiment of the present invention. In step 66, the coupling unit 58 is coupled to the pad 20 in a way as mentioned above. In step 68, the pad 20 with the coupling unit 58 is pressed onto wet cement. In step 70, the cement is allowed to dry and the nut 60, the bottom washer 62a and the bottom screw 64a is permanently fixed inside the dried cement. The outer perimeter of the nut 60 and the bottom washer 62a helps preventing the parts to move or be pulled out of the cement.

After installation, the pad 20 can be easily removed by simply unscrewing the top screw 64b from the nut 60 to release the pad 20. Electronic components, such as LED strip 32 or RF devices are also designed to be able to be removed with the pad 20. For example, the LED strip 32 terminates in a connector 38 as shown in FIG. 4, such that the LED strip 32 can disconnect to adjacent LED strips 32 at the connector 38 when the pad 20 is being removed. Electrical wires connected to the RF devices, if any, can also be disconnected in a similar way. A new pad can then be installed to replace the removed pad. Preferably, the contour on the bottom surface of the new pad is the same as that of the replaced pad to fit the cement.

In a specific application of the replaceable electro-pad in the present invention, the system is employed in a train station or other public transportation stations. When a train arrives at the station, the LED strips emit light to guide users to the nearest exit. The electrical power for the LED strips is supplied from a control room of the train station for example. As the locations of the exits are always the same, the LED strips can be programmed to emit light in a same specific pattern every single time.

In another specific application, a user inputs a specific product within a shop such as a supermarket which he wants to buy into the input device 50 of the remote device 46. The RF reader then sends a signal that includes the product name to the RF device 42 in the pad, and the location of the user is determined by the location information of, for example, the pad with the strongest signal strength. The RF device 42 will then forward the product name information to the backend server. The backend server stores the location of all products within the shop, such as a specific aisle and shelf. It will then retrieve the location information of the specific product upon receiving the signal from the RF receiver 42. The backend server then determines a shortest route of pads from the location of the user to the location of the product. The route of pads will light up to alert the user, and audio directions will also be sent back to the remote device 46 via the RF transmitter 48 of the pad having the strongest signal strength. This audio message can then be played out at the audio output module 52 to guide the user to the desired location.

The exemplary embodiments of the present invention are thus fully described. Although the description referred to particular embodiments, it will be clear to one skilled in the art that the present invention may be practiced with variation of these specific details. Hence this invention should not be construed as limited to the embodiments set forth herein.

For example, the material of the pad 20 can be anything from fiberglass to stainless steel or other materials that may be used in the future. The size and shape of the pad 20 or the depth of the duct can also vary and by no way limit the teachings of the present invention. The protrusions 24 can be truncated cones or directional bars as mentioned above, or can be domes or in other shapes that satisfies the requirement of a specific country.

The embodiments above show one duct portion 26 in each pad 20. It is clear to an ordinary person skilled in the art that any number of duct portions 26 can be provided, and the duct portions 26 can be in any direction as long as it does not affect the protrusions 24. For example, two duct portions 26 can be provided in the pad of FIG. 1 with the two duct portions being perpendicular to each other.

In one embodiment, a duct cover is provided to cover the duct 28 from rain or dust. The duct cover can be resiliently fit onto the duct 28 from the top surface. The duct cover is preferably transparent or yellow to allow the yellow light from the LED strip to penetrate through.

The wireless communication device can be a Wi-Fi device, Bluetooth device or others apart from a RF device. The RF receiver 42 and RF transmitter 44 can also be combined into a transceiver if desired.

In different embodiments, the input device can be a keyboard, keypad, a touch screen, an audio-based input device. In an embodiment, keys of the input device are provided with Braille to allow visually impaired users to identify the keys for input. In different embodiment, the output device can be an audio output device, video output device or a combination of both.

The LED strip 32 can be replaced with other light-emitting components that are small enough to fit into the duct of the pad. The LED strip 32 is only shown as an example of a light-emitting component but not as a limitation.

What is claimed is:

1. A tactile paving pad comprising:
a) a base;
b) a plurality of protrusions extending upwards from said base;
c) a duct portion comprising at least one duct provided on a top surface of said base with an opening provided on said top surface facing upwards, said duct portion extends along a whole length of said base;
d) an electronic component disposed within said duct.

2. The tactile paving pad according to claim 1, wherein said duct portion is located towards a side of said base.

3. The tactile paving pad according to claim 1, wherein said electronic component comprises a light emitting diode strip.

4. The tactile paving pad according to claim 1, wherein said electronic component comprises a wireless communication device.

5. The tactile paving pad according to claim 1, further comprising at least one opening for removably coupling to a coupling unit, wherein said coupling unit comprises a fixed portion and a removable portion, said fixed portion adapted to be fixed to an environment surrounding said fixed portion, said removable portion extends through said opening and removably coupled to said fixed portion.

6. A system comprising:
a) at least one tactile paving pad unit, each unit comprising at least one pad, each pad comprising:
i) a base;
ii) a plurality of protrusions extending upwards from said base;
iii) a duct portion comprising at least one duct provided on a top surface of said base with an opening provided on said top surface, said duct portion extends along a whole length of said base;
iv) a wireless communication device received within said duct;
b) a remote device comprising:
i) a wireless reader adapted to communicate with said wireless communication device;
ii) an input device connected to said wireless reader;
iii) an output device connected to said wireless reader;
c) a backend server adapted to receive information from said remote device;
wherein said backend server retrieves a request for information entered by a user into said input device, and alerts said user with said information through said output device.

7. The system according to claim 6, wherein each said pad further comprises a light emitting diode strip.

8. The system according to claim 6, wherein each said pad further comprising a radio frequency identification tag.

9. The system according to claim 6, wherein each pad further comprising at least one opening for removably coupling to a coupling unit, said coupling unit comprises a fixed portion and a removable portion, said fixed portion adapted to be fixed to an environment surrounding said fixed portion, said removable portion extends through said opening and removably coupled to said fixed portion.

10. A method comprising the steps of:
a) retrieving a location of a specific destination from a user that carries a remote device; said remote device further comprising a wireless reader;
b) identifying a location of said user by identifying a tactile paving pad that is equipped with a wireless communication device and is closest in proximity from said wireless reader; said wireless communication device further installed in a duct portion of said pad;
c) determining a route of tactile paving pads from said location of user to said location of specific destination; and
d) alerting said user of said route.

11. The method of claim 10, wherein said wireless reader comprises a RFID reader and said wireless communication device comprises a RFID tag; said identifying step identifies said tactile paving pad closest in proximity from said wireless reader as a tactile paving pad whose RFID tag responds to said RFID reader.
